(19) United States
(12) Patent Application Publication
(10) Pub. No.: US 2025/0357072 A1
(43) Pub. Date: Nov. 20, 2025

(54) LIQUID SAMPLE HOLDER WITH ELECTROSTATIC MICROSCOPE AND CONTROL METHOD FOR OBSERVING MICROSCOPIC SAMPLES

(71) Applicant: Tamkang University, New Taipei City (TW)

(72) Inventors: Ping-Hung Yeh, New Taipei City (TW); Mei-Yu Chen, New Taipei City (TW); Yi-Ching Ou Yang, New Taipei City (TW); Cheng-En Lee, New Taipei City (TW); Tzu-Hung Ma, New Taipei City (TW)

(73) Assignee: Tamkang University, New Taipei City (TW)

(21) Appl. No.: 19/057,564

(22) Filed: Feb. 19, 2025

(30) Foreign Application Priority Data
May 20, 2024 (TW) 113118662

(51) Int. Cl. H01J 37/16; H01J 37/20; H01J 37/28

(52) U.S. Cl. CPC H01J 37/16; H01J 37/20; H01J 37/28

(57) ABSTRACT

A liquid sample holder with an electrostatic microscope and a control method for adjusting an observation position of a sample to be observed within liquid material. The liquid sample holder includes an upper shell, a lower shell, a limiting layer, and a bearing plate. The upper shell has a thin-film window. The lower shell is aligned with an inner surface of the upper shell, and together they form a sealed cavity filled with liquid material, where a sample to be observed is distributed. The limiting layer and the bearing plate are disposed within the liquid material. The bearing plate locates between the inner surface and the limiting layer. An electron beam generates an electrostatic force that acts on the sample to be observed, the bearing plate, and the 10 limiting layer, thereby attracting the sample to move to a predefined observation area while the limiting layer move towards the inner surface.

### CROSS-REFERENCE TO RELATED APPLICATION

This non-provisional application claims priority under 35 U.S.C. § 119 (a) to patent application Ser. No. 11/311,8662 filed in Taiwan, R.O.C. on May 20, 2024, the entire contents of which are hereby incorporated by reference.

### BACKGROUND

### Technical Field

The present disclosure relates to a bearing device and an observation method for observing samples, and in particular, to a liquid sample holder with an electrostatic microscope and a control method for observing microscopic samples.

### Related Art

Since optical microscopes are limited in observation, electron microscopes are developed, to observe more microscopic objects. Via an electron microscope, nanometer-scale objects can be observed, for example, a crystal structure, an organelle, and an arrangement of atoms. To stabilize a microscopic object, a liquid sample holder is developed as a device for bearing an object to be observed, for observation via a scanning electron microscope (SEM).

The liquid sample holder is usually filled with liquid material, so that a sample can be suspended within the liquid material, and a position of the sample is further controlled. An effective distance of an electron beam of the scanning electron microscope is fixed. Therefore, if the position of the sample is beyond the effective distance of the electron beam, the sample still cannot be observed via the scanning electron microscope. Moreover, the sample is suspended within the liquid material, so that the sample may drift vertically in addition to moving horizontally, which increases the difficulty in observing the sample.

### SUMMARY

In view of this, in an embodiment, an electrostatic microscope is configured with a liquid sample holder and an electron beam generator. The liquid sample holder includes an upper shell, a thin-film window, a lower shell, a limiting layer, and liquid material. The upper shell has a window. The thin-film window is located in the window. The lower shell forms a sealed cavity with the upper shell and the thin-film window. The limiting layer is located in the sealed cavity. The liquid material is provided in the sealed cavity, and includes a sample to be observed. When driven, the electron beam generator generates an electron beam to the thin-film window and the sealed cavity, to enable the thin-film window to generate an electrostatic force to attract the limiting layer. When the sample to be observed is scanned on the liquid sample holder, the electron beam generator generates static electricity to attract the sample to be observed to a predefined observation area, to form a best image.

In an embodiment, the limiting layer has multiple vias. The liquid material passes through the multiple vias. Opening directions of the multiple vias are perpendicular to a normal of an inner surface, or opening directions of the multiple vias are parallel to a normal of an inner surface.

In an embodiment, the electron beam passes through the thin-film window from an outer surface of the upper shell in a direction of an inner surface thereof, and the outer surface and the inner surface are two opposite surfaces of the upper shell.

In an embodiment, the electron microscope further includes a bearing plate, positioned within the liquid material, located between the inner surface and the limiting layer. The electrostatic force attracts the bearing plate and the limiting layer, to enable the bearing plate and the limiting layer to move towards the inner surface.

In an embodiment, an area of the bearing plate is larger than that of the thin-film window.

In an embodiment, the thin-film window is made of a silicon nitride, poly (methyl methacrylate), polycarbonate, polyethylene, or polypropylene.

In an embodiment, the predefined observation area is located on a side of the thin-film window at an inner surface, and a distance between the predefined observation area and the thin-film window ranges from 0.5 to 2 microns (μm).

In an embodiment, a control method for observing microscopic samples is provided. A liquid sample holder is filled with liquid material, and a sample to be observed is distributed within the liquid material, to adjust an observation position of the sample to be observed within the liquid material. The control method for observing microscopic samples includes: an electron beam generator emits an electron beam that passes through a thin-film window of the liquid sample holder, to enable the thin-film window to generate an electrostatic force; and the electrostatic force of the thin-film window attracts the sample to be observed, to limit the sample to be observed in a predefined observation area.

In an embodiment, the step that an electron beam generator emits an electron beam that passes through a thin-film window of the liquid sample holder, to enable the thin-film window to generate an electrostatic force includes: disposing a limiting layer within the liquid material; and attracting, by the electrostatic force of the thin-film window, the limiting layer, to enable the limiting layer to move towards an inner surface of the liquid sample holder.

In an embodiment, the step that an electron beam generator emits an electron beam that passes through a thin-film window of the liquid sample holder, to enable the thin-film window to generate an electrostatic force includes: disposing a bearing plate within the liquid material, where the bearing plate is located between the inner surface and the limiting layer; and attracting, by the electrostatic force of the thin-film window, the bearing plate and the limiting layer, to enable the bearing plate and the limiting layer to move towards the inner surface.

In some embodiments, a liquid sample holder with an electrostatic microscope is provided. The liquid sample holder is configured to adjust an observation position of a sample to be observed within liquid material. The liquid sample holder configured for an electron microscope includes an upper shell, a lower shell, and a limiting layer. The upper shell is provided with a window in which a thin-film window is disposed. The lower shell is aligned with the upper shell, and forms, with the upper shell and the thin-film window, a sealed cavity in which the liquid material is provided. The limiting layer is disposed within the liquid material. An electron beam passes through the thin-film window into the sealed cavity, to enable the thin-film window to generate an electrostatic force to attract the limiting layer and the sample to be observed.

In an embodiment, the limiting layer has multiple vias. The liquid material passes through the multiple vias. Opening directions of the multiple vias are perpendicular to a normal of an inner surface, or opening directions of the multiple vias are parallel to a normal of an inner surface.

In an embodiment, the liquid sample holder further includes a bearing plate, positioned within the liquid material, located between the thin-film window and the limiting layer. The electron beam passes through the thin-film window, and the electrostatic force attracts the bearing plate, the limiting layer, and the sample to be observed.

In an embodiment, an area of the bearing plate is larger than that of the thin-film window.

The liquid sample holder with an electrostatic microscope and the control method for observing microscopic samples are adapted to controlling the sample to be observed within the liquid material, so that the sample to be observed can be attracted into the predefined observation area. The limiting layer, the bearing plate, or a combination thereof is further disposed in the liquid sample holder, so that it can be further ensured that the sample to be observed can be maintained in the predefined observation area, and a humidity of the sample to be observed can be further maintained.

### BRIEF DESCRIPTION OF THE DRAWINGS

FIG. 1 is a three-dimensional view of a liquid sample holder with an electrostatic microscope according to an embodiment.

FIG. 2 is a cross-sectional view of an electron beam generator and a liquid sample holder according to an embodiment.

FIG. 3 is a schematic flowchart of a control method for observing microscopic samples according to an embodiment.

FIG. 4 is a three-dimensional view of a liquid sample holder according to an embodiment.

FIG. 5A is a cross-sectional view before a limiting layer is attracted by an electrostatic force according to an embodiment.

FIG. 5B is a cross-sectional view after a limiting layer is attracted by an electrostatic force according to an embodiment.

FIG. 6 is a three-dimensional view of a liquid sample holder according to an embodiment.

FIG. 7A is a cross-sectional view before a limiting layer and a bearing plate are attracted by an electrostatic force according to an embodiment.

FIG. 7B is a cross-sectional view after a limiting layer and a bearing plate are attracted by an electrostatic force according to an embodiment.

### DETAILED DESCRIPTION

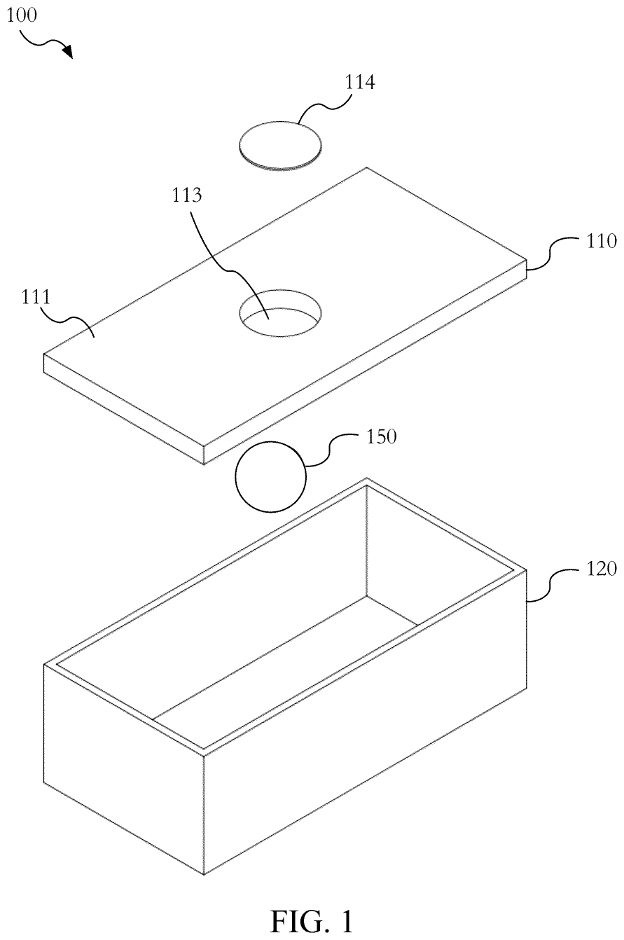

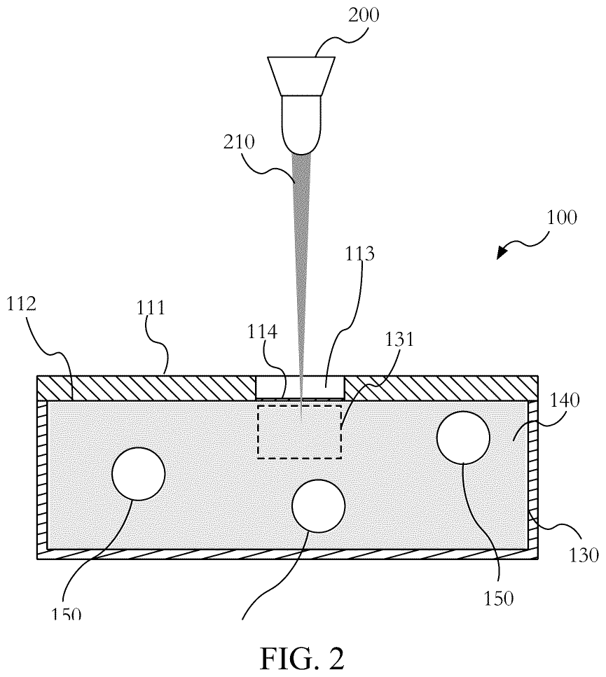

Refer to FIG. 1 and FIG. 2. FIG. 1 is a three-dimensional view of a liquid sample holder with an electrostatic microscope according to an embodiment. FIG. 2 is a cross-sectional view of an electron beam generator and a liquid sample holder according to an embodiment. The liquid sample holder (referred to as a liquid sample holder 100 below) with the electrostatic microscope in this embodiment includes at least an upper shell 110 and a lower shell 120. The liquid sample holder 100 may bear a sample to be observed 150, and is configured for a scanning electron microscope (SEM for short) to observe the sample to be observed 150.

A window 113 is provided in the upper shell 110. The window 113 runs through an outer surface 111 and an inner surface 112 of the upper shell 110. The outer surface 111 and the inner surface 112 are two opposite surfaces. Refer to FIG. 2. A thin-film window 114 is further disposed in a side, located at the inner surface 112, of the window 113. A thickness of the thin-film window 114 is determined by a material of the thin-film window or an intensity of an electron beam 210 of the electron microscope. The material of the thin-film window 114 may be but is not limited to a silicon nitride (Si₃N₄), poly (methyl methacrylate) (PMMA), polycarbonate (PC), polyethylene (PE), or polypropylene (PP). The electron microscope may drive the electron beam generator 200 to emit the electron beam 210. The electron beam 210 passes through the thin-film window 114 to scan the sample to be observed 150.

The lower shell 120 is aligned with the side of the inner surface 112. When the lower shell 120 and the upper shell 110 are assembled, a sealed cavity 130 is formed between the lower shell 120 and the upper shell 110. The sealed cavity 130 may be filled with liquid material 140 and the sample to be observed 150, so that the sample to be observed 150 may be suspended within the liquid material 140. Generally, a depth of the sealed cavity 130 may be 3 mm. In FIG. 2, the sample to be observed 150 is suspended at different positions within the liquid material 140. There is a predefined observation area 131 on a side of the thin-film window 114 at the inner surface 112. The predefined observation area 131 is an area at a best observation distance corresponding to the electron microscope. A range of the predefined observation area 131 may be but is not limited to a space size of 0.25 mm×0.25 mm ×1 μm.

An output result of imaging the sample to be observed 150 by the electron beam 210 may be affected by different depths. Generally, when the sample to be observed 150 is at a great depth within the liquid material 140, an image of the sample to be observed 150 may blur under impact of the intensity of the electron beam 210. The predefined observation area 131 is a best range within which the electron beam 210 is emitted to image the sample to be observed 150. In other words, when the sample to be observed 150 is located in the predefined observation area 131, the sample to be observed 150 can be clearly observed via the electron microscope.

For electron beams 210 with different intensities, there may be different predefined observation areas 131. In FIG. 2, there is a dashed box below the thin-film window 114, and the dashed box is the predefined observation area 131. In some embodiments, a distance between the predefined observation area 131 and the thin-film window 114 ranges from 0.5 to 2 μm. FIG. 2 is used as an example. The distance is a distance between the thin-film window 114 and a closest side of the predefined observation area 131. A depth of the predefined observation area 131 is from the thin-film window 114 to an upper side edge and a lower side edge of the predefined observation area 131. A width of the thin-film window 114 is greater than or equal to that of the predefined observation area 131.

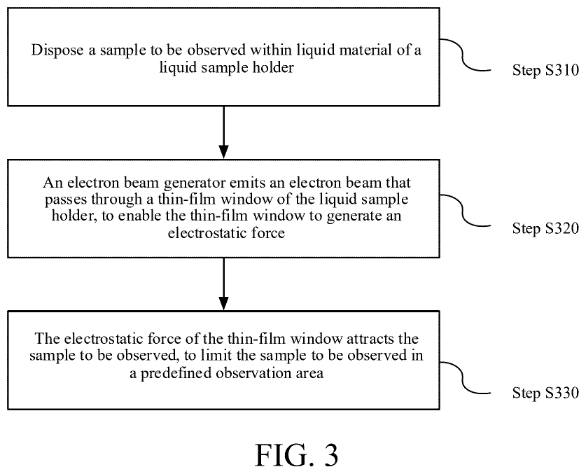

For further description, refer to FIG. 3. FIG. 3 is a schematic flowchart of a control method for observing microscopic samples according to an embodiment. The control method for observing microscopic samples includes at least the following steps.

Step S310: A sample to be observed is disposed within liquid material of a liquid sample holder.

Step S320: An electron beam generator emits an electron beam that passes through a thin-film window of the liquid sample holder, to enable the thin-film window to generate an electrostatic force.

Step S330: The electrostatic force of the thin-film window attracts the sample to be observed, to limit the sample to be observed in a predefined observation area.

First, the sample to be observed 150 is distributed within the liquid material 140 of the liquid sample holder 100 (corresponding to step S310). A user controls the electron microscope, so that the electron microscope outputs the electron beam 210 to irradiate the thin-film window 114 (corresponding to step S320). The electron beam 210 passes through the thin-film window 114 from the outer surface 111 in a direction of the inner surface 112. Since the thin-film window 114 is made of an insulating material, after the electron beam 210 passes through the thin-film window 114, the thin-film window 114 may accumulate charges after irradiated by the electron beam 210, to form an electrostatic force (corresponding to step S320). Negative charges are accumulated on a side from which the electron beam 210 enters the thin-film window 114, and positive charges are inductively generated on a side from which the electron beam leaves the thin-film window 114.

After the thin-film window 114 generates the electrostatic force, the electrostatic force attracts the sample to be observed 150 within the liquid material 140. FIG. 2 is used as an example. The sample to be observed 150 close to the thin-film window 114 is attracted by the electrostatic force. The lower sample to be observed 150 in the center in FIG. 2 is subjected to a strong electrostatic force. The sample to be observed 150 moves towards the inner surface 112, so that the sample to be observed 150 moves to be above the sealed cavity 130 (that is, the predefined observation area 131) (corresponding to step S330).

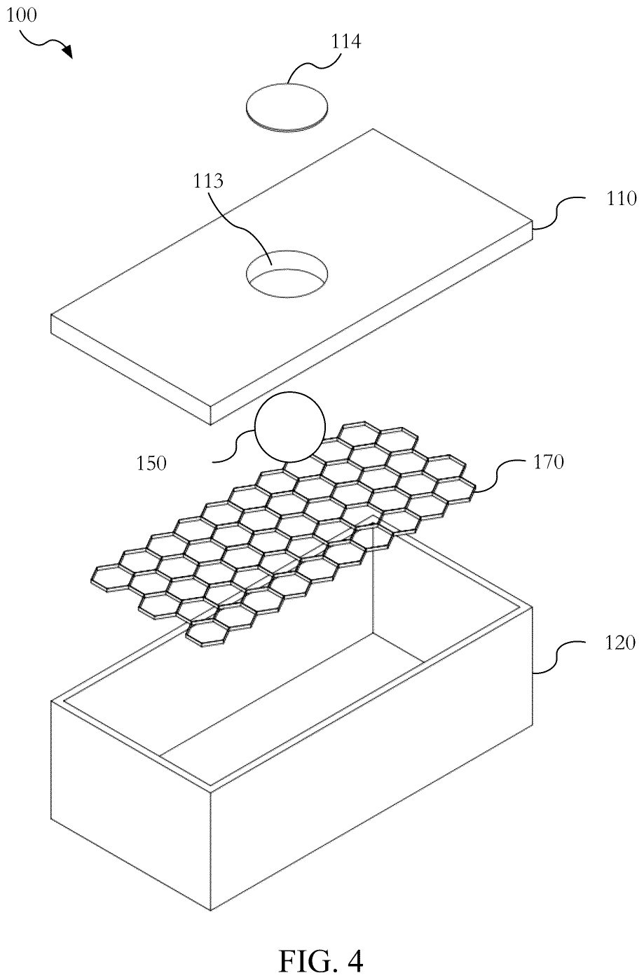

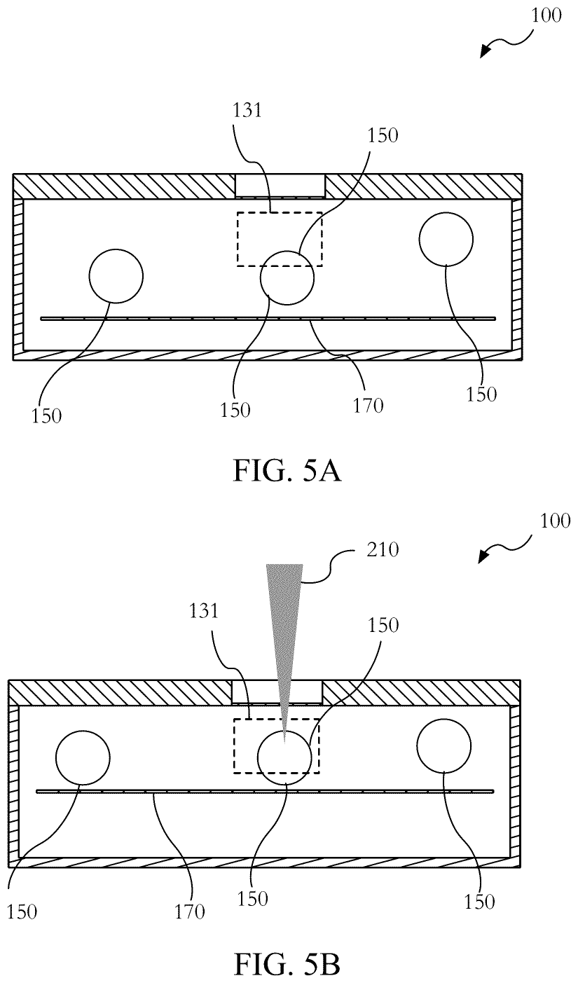

In some embodiments, the liquid sample holder 100 further includes a limiting layer 170. Refer to FIG. 4, FIG. 5A, and FIG. 5B. The limiting layer 170 is disposed within the liquid material 140. An area of the limiting layer 170 is smaller than a cross-sectional area of the sealed cavity 130. The limiting layer 170 is made of a metal or composite, which may be but is not limited to gold, silver, copper, aluminum, iron, nickel, chrome, plumbum, titanium, magnesium, a metal-plastic composite, a carbon fiber-plastic composite, a carbon fiber-metal composite, or the like. After the electron beam 210 passes through the thin-film window 114, in addition to attracting the sample to be observed 150, the electrostatic force may act on the limiting layer 170, so that the limiting layer 170 moves towards the inner surface 112. Since the area of the limiting layer 170 is smaller than a cross-sectional area of the sealed cavity 130, the limiting layer 170 can move upwards, downwards, leftwards, and rightwards within the liquid material 140, as shown in FIG. 5A and FIG. 5B. Alternatively, when the area of the limiting layer 170 is equal to (or slightly smaller than) a cross-sectional area of the sealed cavity 130, the limiting layer 170 can move upwards and downwards within the liquid material 140 in a suspension manner.

In some embodiments, the limiting layer 170 has multiple vias. Refer to FIG. 4. When the limiting layer 170 is disposed within the liquid material 140, the liquid material 140 may pass through the vias, so that the liquid material 140 can remain on both sides of the vias. Generally, the electron beam 210 can be emitted to the predefined observation area 131 with high energy. The liquid material 140 in the predefined observation area 131 may be evaporated, making the predefined observation area 131 difficult to observe. Therefore, the liquid material 140 may continuously refill the predefined observation area 131 through the vias. Opening directions of the vias are perpendicular to a normal of the inner surface 112. Alternatively, opening directions of the vias are parallel to a normal of the inner surface 112. In FIG. 4, the opening directions of the vias is parallel to the normal of the inner surface 112.

In addition, when the limiting layer 170 is subjected to the electrostatic force, the limiting layer 170 moves towards the inner surface 112, and the limiting layer 170 may also induce charges to change charge distribution on both sides of the limiting layer 170. In addition, charges on one side (that is, close to the inner surface 112) of the limiting layer 170 may also act on the sample to be observed 150, so that the sample to be observed 150 is suspended in the predefined observation area 131, or the sample to be observed 150 is supported by the limiting layer 170 to move to the predefined observation area 131.

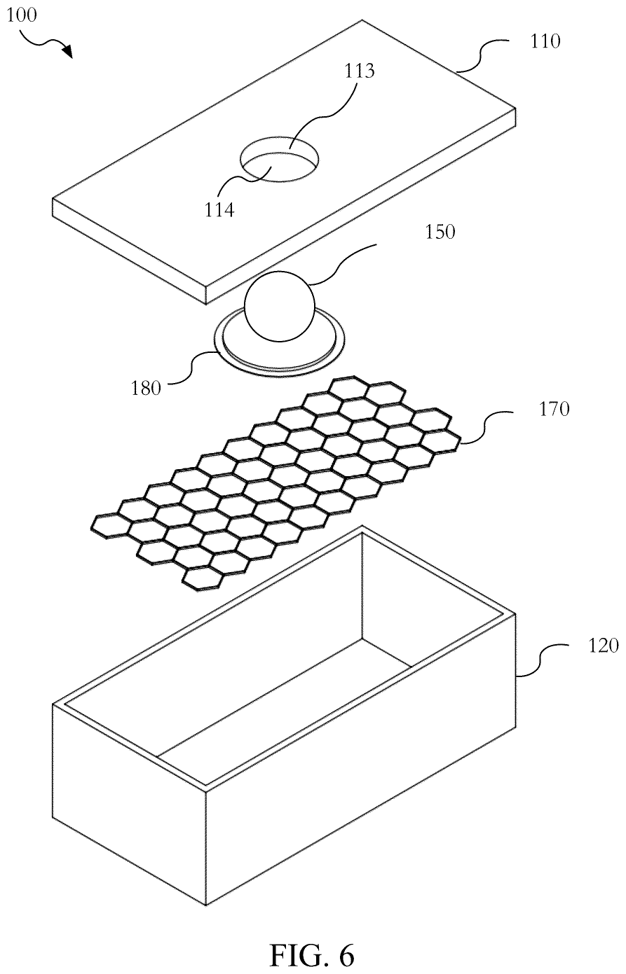

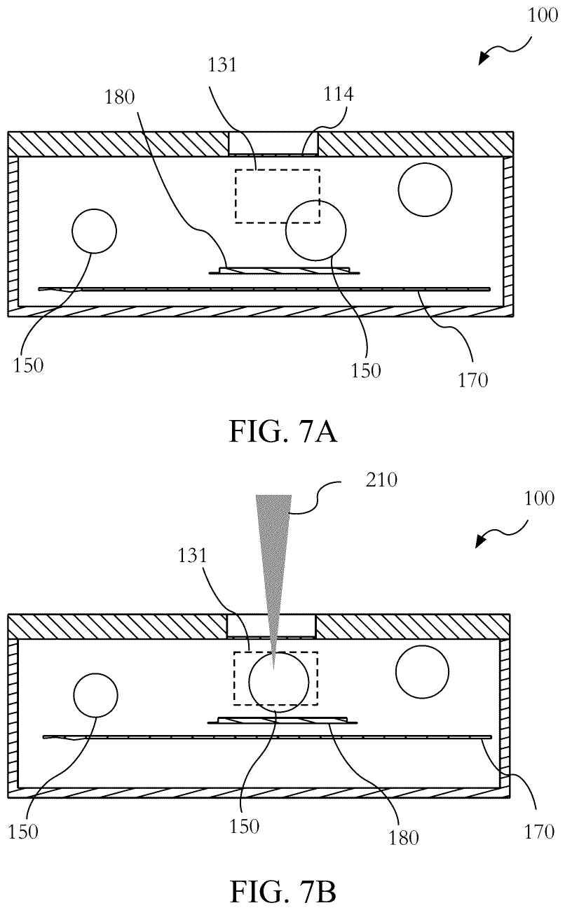

In some embodiments, the liquid sample holder 100 further includes a bearing plate 180. Refer to FIG. 6, FIG. 7A, and FIG. 7B. An area of the bearing plate 180 is greater than or equal to that of the thin-film window 114. For example, the area of the bearing plate 180 is 1.5 times that of the thin-film window 114. A material of the bearing plate 180 may be but is not limited to gold, silver, copper, aluminum, iron, nickel, chrome, plumbum, titanium, magnesium, a metal-plastic composite, a carbon fiber-plastic composite, a carbon fiber-metal composite, or the like. A surface of the bearing plate 180 is a complete plane. An appearance of the bearing plate 180 may be a round, a rectangle, or a polygon, as shown in FIG. 6.

The bearing plate 180 is disposed within the liquid material 140. The bearing plate 180 is located between the inner surface 112 and the limiting layer 170. In FIG. 7A, the electron beam 210 has yet not passed through the thin-film window 114, so that the thin-film window 114 does not have the electrostatic force. Therefore, the bearing plate 180 and the limiting layer 170 each are suspended within the liquid material 140. After the electron beam 210 passes through the thin-film window 114, the electrostatic force acts on the sample to be observed 150, the bearing plate 180, and the limiting layer 170. The sample to be observed 150, the bearing plate 180, and the limiting layer 170 each are subjected to the electrostatic force, to move towards the inner surface 112, as shown in FIG. 7B. When the limiting layer 170 and the bearing plate 180 move, the bearing plate 180 can support the sample to be observed 150, and may further limit the sample to be observed 150 in the predefined observation area 131.

The liquid sample holder 100 with the electrostatic microscope and the control method for observing microscopic samples are adapted to controlling the sample to be observed 150 within the liquid material 140, so that the sample to be observed 150 can be attracted into the predefined observation area 131. The limiting layer 170, the bearing plate 180, or a combination thereof is further disposed in the liquid sample holder 100, so that it can be further ensured that the sample to be observed 150 can be maintained in the predefined observation area 131, a humidity of the sample to be observed 150 can be further maintained, a Brownian movement of the sample to be observed 150 is limited, and a strong electrostatic adsorption effect is enhanced. In addition, the suspended sample to be observed 150 can be limited in the predefined observation area 131 well, so that an image resolution can be effectively improved.

What is claimed is:

1. An electrostatic microscope, comprising:
a liquid sample holder, comprising:
an upper shell, having a window;
a thin-film window, located in the window;
a lower shell, forming a sealed cavity with the upper shell and the thin-film window;
a limiting layer, located in the sealed cavity; and
liquid material, provided in the sealed cavity and comprising a sample to be observed; and
an electron beam generator, configured to generate an electron beam to the thin-film window and the sealed cavity when driven, to enable the thin-film window to generate an electrostatic force to attract the limiting layer.

2. The electrostatic microscope according to claim 1, wherein the limiting layer has a plurality of vias, the liquid material passes through the plurality of vias, and opening directions of the plurality of vias are perpendicular to a normal of an inner surface, or opening directions of the plurality of vias are parallel to a normal of an inner surface.

3. The electrostatic microscope according to claim 1, wherein the electron beam passes through the thin-film window from an outer surface of the upper shell in a direction of an inner surface thereof, and the outer surface and the inner surface are two opposite surfaces of the upper shell.

4. The electrostatic microscope according to claim 3, further comprising a bearing plate, positioned within the liquid material, located between the inner surface and the limiting layer, wherein the electrostatic force attracts the bearing plate and the limiting layer, to enable the bearing plate and the limiting layer to move towards the inner surface.

5. The electrostatic microscope according to claim 4, wherein an area of the bearing plate is larger than that of the thin-film window.

6. The electrostatic microscope according to claim 1, wherein the thin-film window is made of a silicon nitride, poly(methyl methacrylate), polycarbonate, polyethylene, or polypropylene.

7. The electrostatic microscope according to claim 1, wherein a predefined observation area is located on a side of the thin-film window at an inner surface, and a distance between the predefined observation area and the thin-film window ranges from 0.5 to 2 microns (μm).

8. A control method for observing microscopic samples, wherein a liquid sample holder is filled with liquid material, and a sample to be observed is distributed within the liquid material, to adjust an observation position of the sample to be observed within the liquid material, the control method for observing microscopic samples comprising:
emitting, by an electron beam generator, an electron beam that passes through a thin-film window of the liquid sample holder, to enable the thin-film window to generate an electrostatic force; and
attracting, by the electrostatic force of the thin-film window, the sample to be observed, to limit the sample to be observed in a predefined observation area.

9. The control method for observing microscopic samples according to claim 8, wherein the step of emitting, by an electron beam generator, an electron beam that passes through a thin-film window of the liquid sample holder, to enable the thin-film window to generate an electrostatic force comprises:
disposing a limiting layer within the liquid material; and
attracting, by the electrostatic force of the thin-film window, the limiting layer, to enable the limiting layer to move towards an inner surface of the liquid sample holder.

10. The control method for observing microscopic samples according to claim 9, wherein the step of emitting, by an electron beam generator, an electron beam that passes through a thin-film window of the liquid sample holder, to enable the thin-film window to generate an electrostatic force comprises:
disposing a bearing plate within the liquid material, wherein the bearing plate is located between the inner surface and the limiting layer; and
attracting, by the electrostatic force of the thin-film window, the bearing plate and the limiting layer, to enable the bearing plate and the limiting layer to move towards the inner surface.

11. A liquid sample holder with an electrostatic microscope, configured to adjust an observation position of a sample to be observed within liquid material, the liquid sample holder configured for an electron microscope comprising:
an upper shell, provided with a window in which a thin-film window is disposed;
a lower shell, aligned with the upper shell, and forming, with the upper shell and the thin-film window, a sealed cavity in which the liquid material is provided; and
a limiting layer, disposed within the liquid material, wherein
an electron beam passes through the thin-film window into the sealed cavity, to enable the thin-film window to generate an electrostatic force to attract the limiting layer and the sample to be observed.

12. The liquid sample holder with an electrostatic microscope according to claim 11, wherein the limiting layer has a plurality of vias, the liquid material passes through the plurality of vias, and opening directions of the plurality of vias are perpendicular to a normal of the thin-film window, or opening directions of the plurality of vias are parallel to a normal of the thin-film window.

13. The liquid sample holder with an electrostatic microscope according to claim 11, further comprising a bearing plate, positioned within the liquid material, located between the thin-film window and the limiting layer, wherein the electron beam passes through the thin-film window, and the electrostatic force attracts the bearing plate, the limiting layer, and the sample to be observed.

14. The liquid sample holder with an electrostatic microscope according to claim 13, wherein an area of the bearing plate is larger than that of the thin-film window.
